(19) United States
(12) Patent Application Publication
(10) Pub. No.: US 2008/0078531 A1
(43) Pub. Date: Apr. 3, 2008

(54) Heat pipe and manufacturing method thereof

(75) Inventors: Ming-Te Chung, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/790,857

(22) Filed: Apr. 27, 2007

(30) Foreign Application Priority Data
Sep. 29, 2006 (TW) 95136196

(51) Int. Cl. H05K 7/20; F28D 15/02

(52) U.S. Cl. 165/104.33; 29/890.032; 72/253.1

(57) ABSTRACT

A heat pipe includes a hollow annular body with two open ends and two bending portions. A wick structure is formed at an inner surface of the annular body. The bending portions are respectively disposed at the two open ends to form a sealed space within the hollow annular body. A working fluid is filled in the sealed space. Also, a method of manufacturing a heat pipe including steps of: providing a hollow annular body with two open ends, and a wick structure is formed at an inner surface of the hollow annular body; and forming two bending portions respectively at the two open ends to form a sealed space within the hollow annular body, and a working fluid is filled in the sealed space.

### BACKGROUND OF THE INVENTION

This Non-provisional application claims priority under U.S.C. § 119(a) on Patent Application No(s). 095136196, filed in Taiwan, Republic of China on Sep. 29, 2006, the entire contents of which are hereby incorporated by reference.

1. Field of the Invention

The present invention relates to a heat pipe and a manufacturing method thereof, and in particular to a flat heat pipe with low cost and high efficiency.

2. Description of the Related Art

Increased numbers of transistors deployed in a unit area of an electronic element produce considerable heat during operation. Heat pipes provide a simple and effective heat dissipation solution, and are thus widely used. Heat dissipation is achieved by way of energy transmitted through the phase change between gas and liquid of a working fluid. During vaporization, the working fluid removes heat energy from a heat source. Vapor produced fills a vacuum within the pipe. During condensation, vapor in the vacuum is condensed into liquid and releases heat energy. The working fluid flows back to the vaporization area by capillarity of the wick within the heap pipe, thus continuously and effectively transmitting and dissipating heat from the heat source.

A plate heat pipe, while utilizing the same principle as a conventional heat pipe, provides increased conductive surface and is light, thin, short and small, allowing wide applications in electronic devices with large dissipating surface. Generally, the plate heat pipe is assembled by two flat plates, a sealed space is formed between the plates, and a wick structure is formed at the inner surfaces of the flat plates.

FIG. 1 is a schematic view of a plate heat pipe 10, including an upper plate 12 and a lower plate 14 corresponding to each other. A welding material 13 is applied on the joint of the upper plate 12 and the lower plate 14 for connection. A wick structure 15 is formed at the inner surfaces of the upper plate 12 and the lower plate 14. During welding of the upper plate 12 and the lower plate 14, however, welding material is packed into the inner surface of the upper and lower plates, such that discontinued sections 121, 141 of wick structure are formed at the inner surface. However, the discontinued sections 121, 141 of wick structure not only block the path of heat conduction, but also affect heat-conducting efficiency of the plate heat pipe 10.

Conventional heat pipe utilizes welding to connect two flat plates. The welding joint between two plates is long and unreliable, and further causes discontinuity of the wick structure on the inner surface of the plates. In addition, in a large flat heat pipe 10, the center portions of the upper plate 12 and the lower plate 14 lack support, such that partially bending or deformation may occur on the plate heat pipe 10, affecting overall structure of the flat heat pipe 10 and degrading heat conduction of the flat heat pipe 10.

Furthermore, conventional welding of upper and lower plates increases costs for both materials and fabrication.

### BRIEF SUMMARY OF THE INVENTION

The present invention provides a flat heat pipe and manufacturing method thereof. Two seals on two ends of an integrally formed annular body form a sealed space, substituting the conventional welding connection between the two separate panels. Complicated manufacturing elements are thus eliminated, simplifying manufacturing process.

The flat heat pipe includes a hollow annular body, which is flat. The hollow annular body has two open ends. A wick structure is formed at an inner surface of the hollow annular body. Two bending portions disposed at the two open ends, respectively, form a sealed space within the hollow annular body. A working fluid is filled in the sealed space.

The present invention provides a manufacturing method for a flat heat pipe including a step of: providing a hollow annular body, which is flat, wherein the hollow annular body has two open ends. A wick structure is formed at an inner surface of the hollow annular body. The method further includes a step of: forming two bending portions on the two open ends, respectively, to form a sealed space within the hollow annular body. A working fluid is filled in the sealed space.

The hollow annular body is integrally formed as a single piece by extruding or drawing. The bending portions are respectively formed at the two open ends by a jig, such as a punching machine. The hollow annular body is elliptical, a semicircular, rectangular, triangular, square, trapezoidal, pentagonal, hexagonal, octagonal, equilateral polygonal, or scalene in cross section. Material of the hollow annular body includes a heat-conductive material, and the heat-conductive material is of aluminum, copper, titanium, molybdenum, silver, stainless steel, carbon steel or other alloy.

The hollow annular body further includes at least one support member, disposed within the spaces of the hollow annular body so as to form a plurality of chambers. A wick structure is disposed between the inner surface of the hollow annular body and the surfaces of the support member so as to form a continuous wick structure. The support member increases the intensity of the hollow annular body and the area of the wick structure. The support member may be a flat panel, a curved panel or other shape with equivalent functions.

The wick structure is formed by sintering, adhering, packing, deposition or a combination thereof. Material of the wick structure includes plastic, metal, alloy, or porous nonmetal. The wick structure is spring-like metal, cannelure metal, columnar metal, meshed metal or porous structure formed by metal powder injection. The working fluid is inorganic compound, purified water, alcohol, ketone, liquid metal, refrigerant, inorganic compound or a combination thereof.

The heat pipe contacts a heat source, directly or via a base, transmitting heat from the heat source to the heat pipe. The base is a solid metal block. The heat source is an electronic device which produces heat. The electronic device is a central processing unit, a transistor, a server, a graphic card, a hard drive, a power supply, a traffic control system, a multi-media electronic structure, a wireless access point, or a game machine.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view of a conventional plate heat pipe;

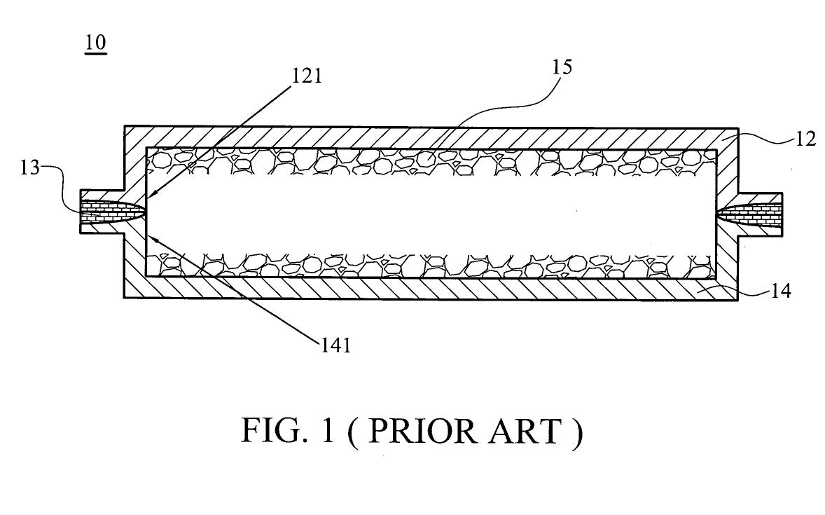

FIG. 2A is an enlarged view of an embodiment of a flat heat pipe of the present invention;

FIG. 2B is a schematic view of a bending portion of the flat heat pipe in FIG. 2A;

FIG. 2C is a sectional view of the flat heat pipe in FIG. 2A;

FIG. 3 is a schematic view of a variant embodiment of a flat heat pipe of the present invention;

FIG. 4 is a sectional view of the flat heat pipe in FIG. 3;

FIG. 5A is a schematic view of another variant embodiment of a flat heat pipe of the present invention;

FIG. 5B is a sectional view of the flat heat pipe in FIG. 5A;

FIG. 6A is a schematic view of another variant embodiment of a flat heat pipe of the present invention; and

FIG. 6B is a sectional view of the flat heat pipe in FIG. 6A.

### DETAILED DESCRIPTION OF THE INVENTION

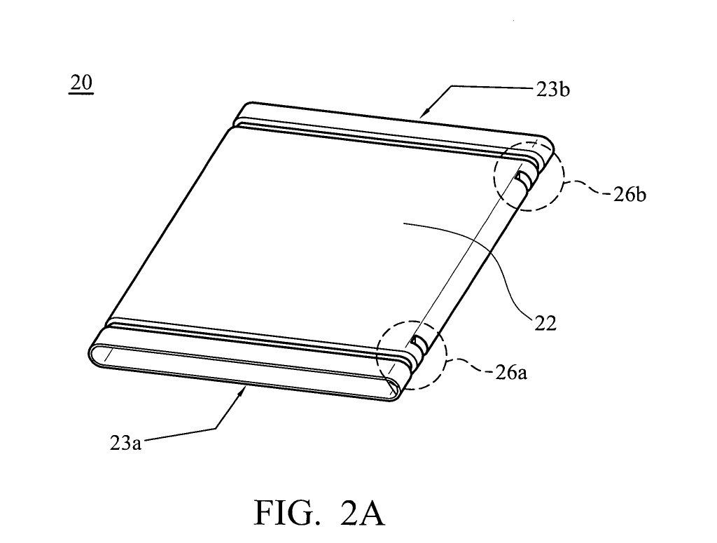

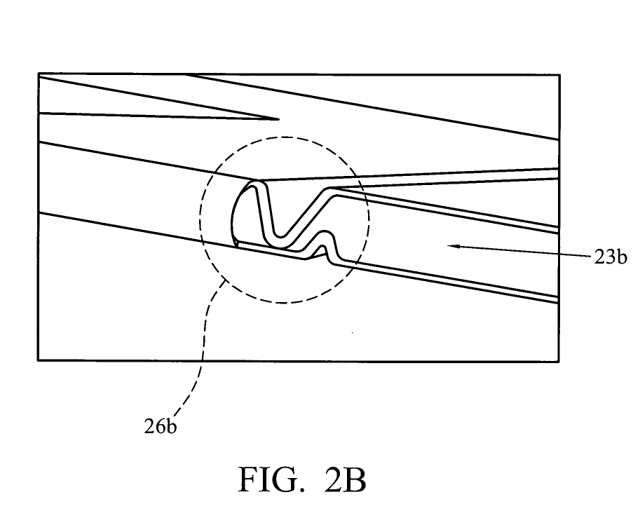

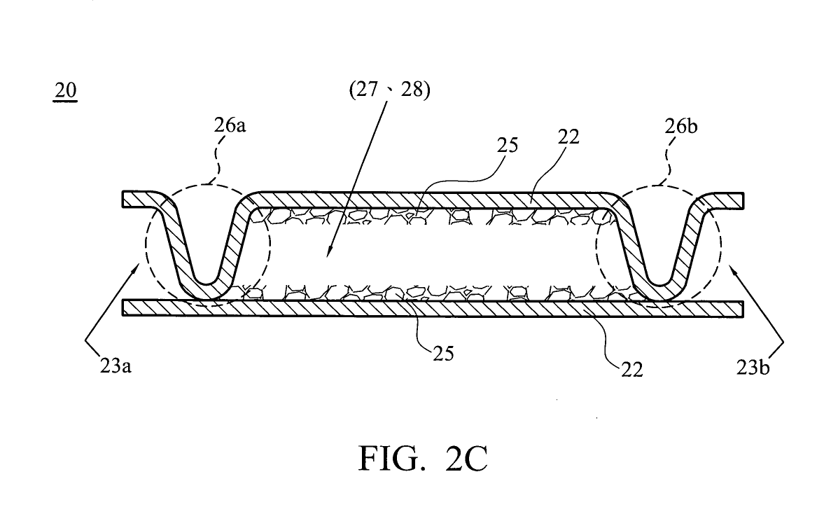

Referring to FIGS. 2A and 2C; FIG. 2A is a schematic view of an embodiment of a flat heat pipe of the invention, and FIG. 2C is a sectional view of the flat heat pipe in FIG. 2A. In FIG. 2A, a flat heat pipe 20 includes a hollow annular body 22, which is flat, with two open ends 23a, 23b. A wick structure 25 is formed between an inner surface of the hollow annular body 22. Two bending portions 26a, 26b are disposed at the two open ends 23a, 23b, respectively, to form a sealed space 27 within the hollow annular body 22. A working fluid 28 is filled in the sealed space 27.

Referring to FIGS. 2A and 2B; FIG. 2B is an enlarged view of a bending portion of the flat heat pipe in FIG. 2A. The annular body 22 is integrally formed as a single piece by extruding or drawing. The bending portions 26a, 26b are respectively formed at the two open ends 23a, 23b of the annular body 22 by a jig, such as a punching machine, allowing a sealed space 27 to be formed in the annular body 22, as shown in FIG. 2C. The annular body 22 includes a highly heat-conductive material, such as aluminum, copper, titanium, molybdenum, silver, stainless steel, carbon steel or other alloy. Additionally, the annular body 22 is elliptical, semicircular, rectangular, triangular, square, trapezoidal, pentagonal, hexagonal, octagonal, equilateral polygonal, or scalene in cross section. A connecting portion between the bending portion 26a, 26b and the inner surface of the annular body 22 is performed by welding, soldering or brazing to enhance the sealing ability of the heat pipe 20.

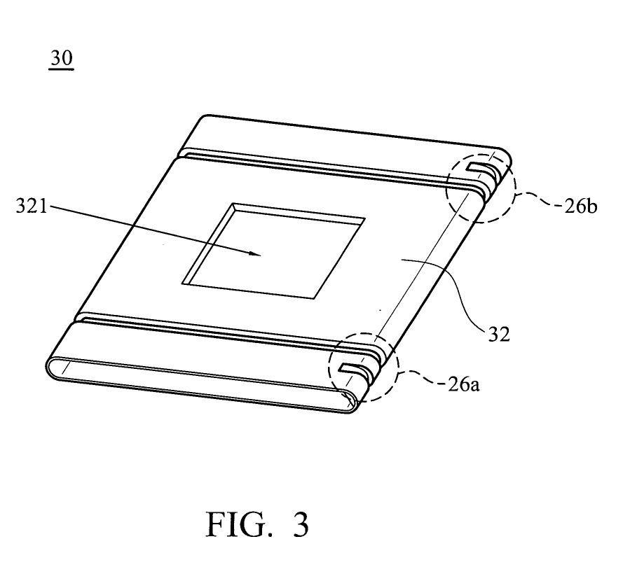

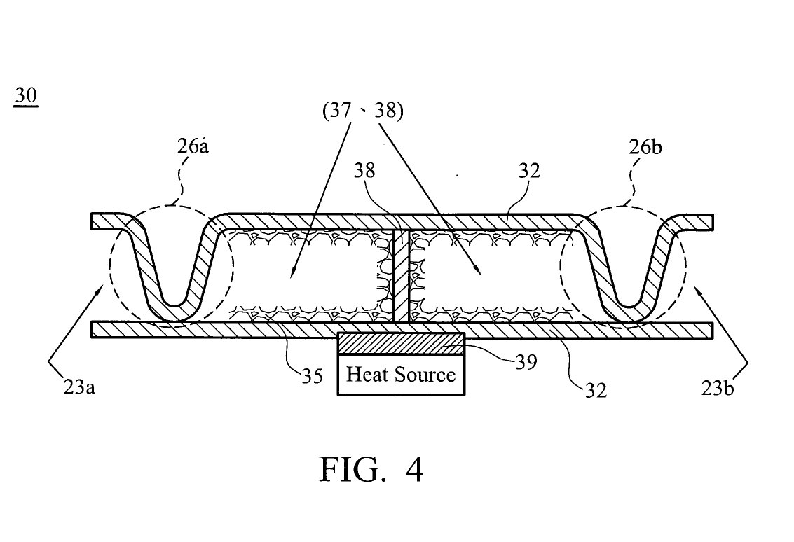

Referring to FIGS. 3 and 4; FIG. 3 is a schematic view of another embodiment of a flat heat pipe of the invention, and FIG. 4 is a sectional view of the flat heat pipe in FIG. 3. In this embodiment, the flat heat pipe 30 has the same reference numerals as the flat heat pipe 20 of FIG. 2A when the numbered elements retain the same function. The flat heat pipe 30 and the flat heat pipe 20 in the previous embodiment is different in that the annular body 32 of the flat heat pipe 30 can further include a support member 38 to form a plurality of chambers 37 within the annular body 32, with the working fluid 28 filled in each of the chambers 37. Each chamber 37 is isolated from others to form an independent enclosed space. Alternatively, each chamber 37 communicates with others, as long as the sealed space is collectively formed within the flat heat pipe 30.

Because the wick structure 35 is disposed between the inner surface of the annular body 32 and the surface of the support member 38, continuity of the wick structure 35 is achieved. Also, the support member 38 enhances intensity of the hollow annular body 32 and the occupancy of the wick structure 35. The support member 38 is a flat panel, a curved panel or has a shape with equivalent functions.

The wick structure is formed by sintering, adhering, packing, deposition or a combination thereof. The wick structure 35 includes plastic, metal, alloy, or porous nonmetal. The wick structure 35 is spring-like metal, cannelure metal, columnar metal, meshed metal or porous structure formed by metal powder injection. The working fluid 28 is inorganic compound, purified water, alcohol, ketone, liquid metal, refrigerant, organic compound or a combination thereof.

Furthermore, the flat heat pipe 30 contacts a heat source, directly or via a base 39 transmitting heat from the heat source to the flat heat pipe 30. The base 39 is a solid metal block, with size thereof not limited, allowing conformity with the heat source. Additionally, the hollow annular body 32 includes a recess 321 at the base 39, for containing and positioning the base 39, as shown in FIG. 3. The heat source is an electronic device, producing heat, such as a central processing unit, a transistor, a server, a graphic card, a hard drive, a power supply, a traffic control system, a multi-media electronic structure, a wireless access point, or a game machine. However, the present invention is not limited thereto. The flat heat pipe 20 in FIG. 2 directly contacts a heat source, for fast dissipation of heat therefrom.

The manufacture method of the flat heat pipe includes a step of: providing a hollow annular body by extruding or drawing, allowing the hollow annular body to be integrally formed as a single piece. The hollow annular body is elliptical, a semicircular, rectangular, triangular, square, trapezoidal, pentagonal, hexagonal, octagonal, equilateral polygonal, or scalene in cross section. The hollow annular body includes a highly heat-conductive material, such as aluminum, copper, titanium, molybdenum, silver, stainless steel, carbon steel or other alloy. The hollow annular body is then mechanically processed to be flat, wherein the flat, hollow annular body has two open ends. A wick structure is formed at an inner surface of the hollow annular structure by sintering, adhering, packing, deposition or a combination thereof. The wick structure is spring-like metal, cannelure metal, columnar metal, meshed metal or porous structure formed by metal powder injection.

A hole is made on the hollow annular body for filling in a working fluid and evacuation. Permanent deformation by punching or stamping at the two open ends of the hollow annular body forms two bending portions and a sealed space. No welding connection between the upper and lower panels of the conventional plate heat pipe is required, efficiently completing the manufacturing process. Not only are manufacturing elements decreased, but the manufacturing process is also simplified.

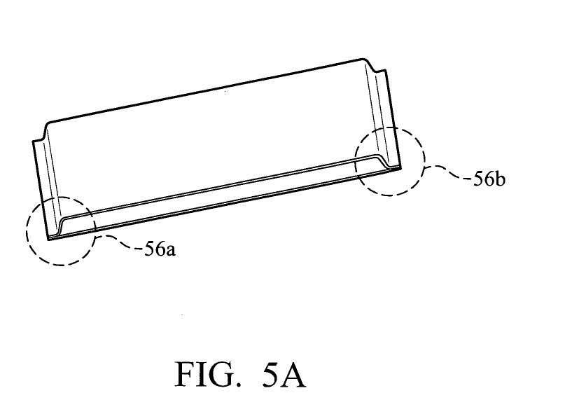

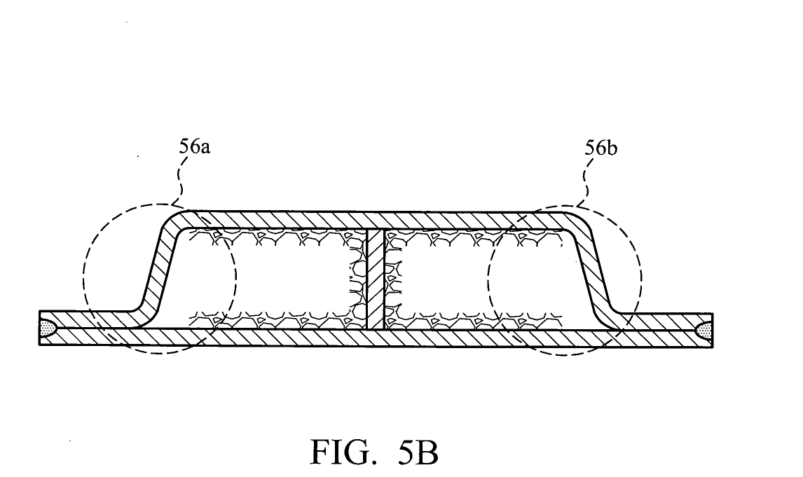

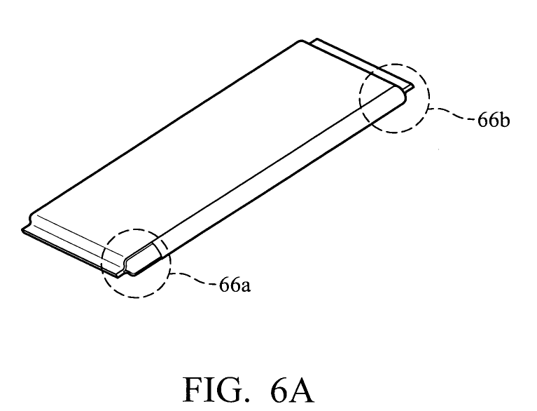

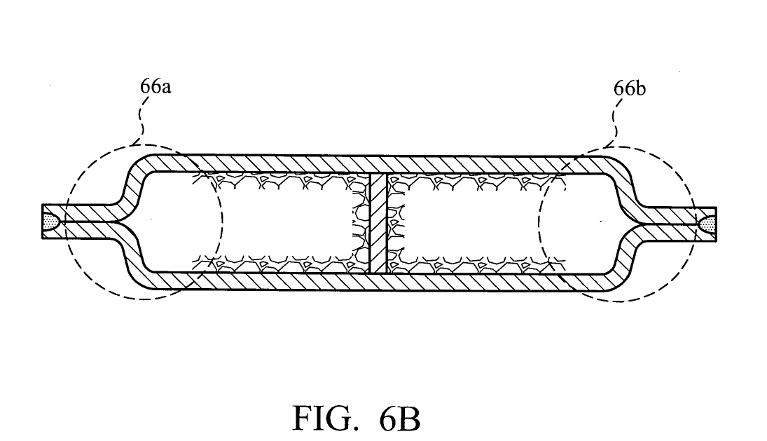

The formation of the bending portions 26a, 26b is not limited to that described in FIGS. 2A to 4. For example, referring to FIGS. 5A and 5B, force can be applied to only one side of the hollow annular body, forming the bending portions 56a, 56b, and a sealed space. Conversely, referring to FIGS. 6A and 6B, force can be applied on two sides of the hollow annular body, permanently deforming the hollow annular body to form the bending portions 66a, 66b, and a sealed space.

The flat heat pipe and manufacturing method thereof minimizes requirement for the welding joint and increases reliability by the integrally formed annular body rather than conventional two welded panels. Additionally, continuity of the wick structure is achieved to improve circulation of the working fluid in the sealed space, increasing heat-dissipating efficiency. Compared to the conventional flat heat pipe with a discontinued portion of the wick structure, the flat heat pipe of the present invention provides a more efficient heat-conduction path.

Moreover, for a flat heat pipe, at least one support member is provided at the weak point of the structure, avoiding bending or deformation of the flat heat pipe with a large size. The destruction of overall structure of the flat heat pipe, and the ceasing of the heat conduction are therefore prevented.

According to the manufacturing method of the flat heat pipe, the flat heat pipe can be sintered at once. The length of the flat heat pipe is adjustable according to different demands. The cost of mold is less. A plurality of flat heat pipe can be produced during the sintering. Therefore, the manufacturing process is simplified. In conclusion, the manufacturing method of the flat heat pipe provides various heat pipes with different geometric shapes, and lowered manufacturing cost.

While the present invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat pipe, comprising a hollow annular body with two open ends and two bending portions; wherein a wick structure is formed at an inner surface of the hollow annular body, the bending portions are respectively disposed at the two open ends to form a sealed space within the hollow annular body, and a working fluid is filled in the sealed space.

2. The heat pipe as claimed in claim 1, wherein the hollow annular body is integrally formed as a single piece by extruding or drawing.

3. The heat pipe as claimed in claim 2, wherein after the hollow annular body is integrally formed as a single piece, the hollow annular body is mechanically processed to be flat.

4. The heat pipe as claimed in claim 1, wherein the bending portions are respectively formed at the two open ends by a jig.

5. The heat pipe as claimed in claim 4, wherein the jig is a punching machine.

6. The heat pipe as claimed in claim 1, wherein after the bending portions are formed, a connecting portion between the bending portions and the inner surface is performed by welding, soldering or brazing to enhance the sealing ability of the heat pipe.

7. The heat pipe as claimed in claim 1, wherein the hollow annular body comprises at least one support member to form a plurality of chambers, and the working fluid is filled in the plurality of chambers.

8. The heat pipe as claimed in claim 7, wherein each of the chambers is isolated to form an independent enclosed space, or each of the chambers communicates with others to collectively form the sealed space.

9. The heat pipe as claimed in claim 7, wherein the wick structure is disposed between the inner surface of the hollow annular body and a surface of the support member to form the continuous wick structure.

10. The heat pipe as claimed in claim 7, wherein the support member increases intensity of the hollow annular body and the occupancy of the wick structure, and the support member comprises a flat panel, a curved panel or a shape with equivalent functions.

11. A method of manufacturing a heat pipe, comprising steps of:
providing a hollow annular body with two open ends, and a wick structure is formed at an inner surface of the hollow annular body; and
forming two bending portions respectively at the two open ends to form a sealed space within the hollow annular body, and a working fluid is filled in the sealed space.

12. The method of manufacturing a heat pipe as claimed in claim 11, wherein the hollow annular body is integrally formed as a single piece by extruding or drawing.

13. The method of manufacturing a heat pipe as claimed in claim 12, wherein after the hollow annular body is integrally formed as a single piece, the hollow annular body is mechanically processed to be flat.

14. The method of manufacturing a heat pipe as claimed in claim 11, wherein the bending portions are respectively formed at the two open ends by a jig.

15. The method of manufacturing a heat pipe as claimed in claim 14, wherein the jig is a punching machine.

16. The method of manufacturing a heat pipe as claimed in claim 11, wherein after the bending portions are formed, a connecting portion between the bending portions and the inner surface is performed by welding, soldering or brazing to enhance the sealing ability of the heat pipe.

17. The method of manufacturing a heat pipe as claimed in claim 11, wherein the hollow annular body comprises at least one support member to form a plurality of chambers, and the working fluid is filled in the plurality of chambers.

18. The method of manufacturing a heat pipe as claimed in claim 17, wherein each of the chambers is isolated to form an independent enclosed space, or each of the chambers communicates with the others to collectively form the sealed space.

19. The method of manufacturing a heat pipe as claimed in claim 17, wherein the wick structure is disposed between the inner surface of the hollow annular body and a surface of the support member to form the continuous wick structure, the support member increases intensity of the hollow annular body and the occupancy of the wick structure, and the support member comprises a flat panel, a curved panel, or shape with equivalent functions.

20. The method of manufacturing a heat pipe as claimed in claim 11, wherein the hollow annular body is elliptical, a semicircular, rectangular, triangular, square, trapezoidal, pentagonal, hexagonal, octagonal, equilateral polygonal, or scalene in cross section, the hollow annular body comprises a heat-conductive material, such as aluminum, copper, titanium, molybdenum, silver, stainless steel, carbon steel or other alloy.
